(19) United States
(12) Patent Application Publication
(10) Pub. No.: US 2023/0057192 A1
(43) Pub. Date: Feb. 23, 2023

(54) COMPENSATION CIRCUIT MODULE, POWER AMPLIFICATION ASSEMBLY, COMPENSATION METHOD AND DEVICE

(71) Applicant: SMARTER MICROELECTRONICS (GUANG ZHOU) CO., LTD., Guangzhou (CN)

(72) Inventors: Qiang SU, Guangzhou (CN); Baiming XU, Guangzhou (CN); Zhenfei PENG, Guangzhou (CN)

(73) Assignee: SMARTER MICROELECTRONICS (GUANG ZHOU) CO., LTD., Guangzhou (CN)

(21) Appl. No.: 17/929,188

(22) Filed: Sep. 1, 2022

Related U.S. Application Data
(63) Continuation of application No. PCT/CN2021/135812, filed on Dec. 6, 2021.

(30) Foreign Application Priority Data
Aug. 20, 2021 (CN) 202110961458.3

(51) Int. Cl. H03F 1/32; H03F 3/24; H03F 1/02

(52) U.S. Cl. CPC H03F 1/3247; H03F 3/245; H03F 1/0222; H03F 2200/451; H03F 2201/3233

(57) ABSTRACT

A compensation circuit module includes a variable resistor, a detection component and a control component. A detection end of the detection component is connected with a DC blocking capacitor of the power amplifier and is configured to detect a voltage swing of an input signal of the DC blocking capacitor. The control component is connected with the detection component and is configured to output a control signal according to the input signal detected by the detection component. The variable resistor is connected with the output end of the control component and is configured to change the resistance connected to the power amplifier according to the control signal, and the resistance of the variable resistor connected to the power amplifier is configured to constitute the feedback resistance of the power amplifier.

### CROSS-REFERENCE TO RELATED APPLICATIONS

This is a continuation of International Application No. PCT/CN2021/135812 filed on Dec. 6, 2021, which claims priority to Chinese Patent Application No. 202110961458.3 filed on Aug. 20, 2021. The disclosures of the above-referenced applications are hereby incorporated by reference in their entirety.

### BACKGROUND

For a power amplifier, using amplitude modulation to amplitude modulation distortion (abbreviated as AM-AM) and amplitude modulation to phase modulation distortion (AM-PM), the output power amplified by the front-end power amplifier and the performance of adjacent channel leakage ratio (abbreviated as ACLR) can be characterized.

### SUMMARY

The disclosure relates to the field of electronic technology, and in particular to a compensation circuit module, a power amplification assembly, a compensation method and a device.

The disclosure provides a compensation circuit module, a power amplification assembly, a compensation method and a device.

According to the first aspect of the present disclosure, a compensation circuit module is provided, and the compensation circuit module at least includes a variable resistor, a detection component and a control component.

The detection component has a detection end which is connected with a DC blocking capacitor of a power amplifier and is configured to detect a voltage swing of an input signal of the DC blocking capacitor.

The control component is connected with the detection component, and is configured to output a control signal according to the input signal detected by the detection component.

The variable resistor is connected with an output end of the control component, and is configured to change a resistance connected to the power amplifier according to the control signal. The resistance, connected to the power amplifier, of the variable resistor is configured to form a feedback resistance of the power amplifier. The feedback resistance is configured to increase as gain of the power amplifier decreases. The increased feedback resistance is configured to keep the gain in a straight section of a gain change curve.

According to the second aspect of the present disclosure, there a power amplification assembly is provided, which includes a power amplifier and the compensation circuit module provided in the first aspect. The power amplifier at least comprises a DC blocking capacitor arranged at a signal input end, a transistor, a bias circuit, a feedback circuit and a DC blocking capacitor arranged at a signal output end.

A first end of the feedback circuit is connected with the DC blocking capacitor at the signal input end, the bias circuit and the gate of the transistor. A second end of the feedback circuit is connected with the DC blocking capacitor at the signal output end and the drain of the transistor. The feedback resistor of the feedback circuit includes at least a fixed resistor and a variable resistor connected to the feedback circuit, the fixed resistor and the variable resistor are configured to form a feedback resistance of the power amplifier. The feedback resistance is configured to increase when the gain of the power amplifier decreases. The increased feedback resistance is configured to keep the gain in the straight section of the gain change curve.

According to the third aspect of the present disclosure, a method for compensation is provided, which utilizes the compensation circuit module provided in the above first aspect to compensate the gain of the power amplifier provided in the above second aspect, and the method includes detecting an input signal of the DC blocking capacitor by the detection component; outputting a control signal by the control component according to the input signal of the DC blocking capacitor, in which, the control signal is configured to change the resistance connected to the power amplifier, the resistance, connected to the power amplifier, of the variable resistor and the fixed resistor constitute a feedback resistance. The feedback resistance is configured to increase when the gain of the power amplifier decreases. The increased feedback resistance is configured to keep the gain in the straight section of the gain change curve.

According to a fourth aspect of some embodiments of the present disclosure, a device is provided, which comprises a memory and a processor.

The processor is connected to the memory, and is configured to implement the operations in the compensation method provided in the above third aspect by the computer execution instructions stored in the memory.

It should be understood that the above general description and the following detailed description are exemplary and explanatory only, and do not limit the present disclosure. Other features of embodiments of the disclosure will become apparent from the following detailed description of exemplary embodiments with reference to the drawings.

### BRIEF DESCRIPTION OF THE DRAWINGS

The drawings here are incorporated into the specification and constitute a part of the specification, the drawings show some embodiments in accordance with the disclosure and together with the specification, serve to explain various technical solutions of embodiments of the disclosure.

FIG. 1 is a circuit structure diagram of a power amplifier according to some embodiments.

FIG. 2 is a curve showing the change of gain AM-AM with the resistance of feedback resistor according to some embodiments.

FIG. 3 is a schematic structural diagram of a compensation circuit module according to some embodiments.

FIG. 4 is a schematic structural diagram of a compensation circuit module according to some embodiments.

FIG. 5 is a schematic structural diagram of a compensation circuit module according to yet some embodiments.

FIG. 6 is a schematic circuit structure diagram of a compensation circuit module according to some embodiments.

FIG. 7 is another schematic circuit structure diagram of a compensation circuit module according to some embodiments.

FIG. 8 is a simplified schematic diagram of the circuit structure of a compensation circuit module according to some embodiments.

FIG. 9 is a schematic diagram of the change of the first control current Ic of a compensation circuit module with the input power Pin of the power amplifier according to some embodiments.

FIG. 10 is a schematic diagram of the change of the current control voltage Vc of a compensation circuit module with the first control current Ic according to some embodiments.

FIG. 11 is a schematic diagram of the change of the resistance Requ of the variable resistor of the compensation circuit module with the control voltage Vc1 according to some embodiments.

FIG. 12 is a schematic diagram showing the change of the feedback resistance Rtotal of the compensation circuit module with the control voltage Vc1 according to some embodiments.

FIG. 13 is a schematic diagram of the change of the feedback resistance Rtotal of the compensation circuit module with the input power Pin of the power amplifier according to some embodiments.

FIG. 14 is a schematic diagram of the gain AM-AM of the power amplifier with the first control voltage Vcon1 according to some embodiments.

FIG. 15 is a schematic diagram of the gain AM-AM of the power amplifier with the first control voltage Vcon2 according to some embodiments.

FIG. 16 is a schematic diagram of a circuit structure of a variable resistor according to some embodiments.

FIG. 17 is a schematic diagram of a circuit structure of a variable resistor according to some embodiments.

FIG. 18 is a schematic diagram of a circuit structure of a variable resistor shown in some embodiments.

FIG. 19 is a schematic diagram of a variable resistance curve shown in some embodiments.

FIG. 20 is a schematic structural diagram of a power amplification assembly according to some embodiments.

FIG. 21 is a schematic diagram of the circuit structure of a power amplification assembly according to some embodiments.

FIG. 22 is a flowchart of a compensation method according to some embodiments.

FIG. 23 is a flowchart of a compensation method according to some embodiments.

FIG. 24 is a flowchart of a compensation method according to yet some other embodiments.

### DETAILED DESCRIPTION

Various exemplary embodiments, features and aspects of the disclosure are described in detail below with reference to the drawings. In the drawings, the same reference numerals refer to elements with the same or similar functions. Although various aspects of some embodiments are shown in the drawings, the drawings are not necessarily drawn to scale unless otherwise indicated.

The special word “exemplary” here means “serving as an example, embodiment or illustration”. Any embodiment described herein as “exemplary” need not be interpreted as superior to or better than other embodiments.

In this disclosure, the term “and/or” is only a kind of relation describing related objects, which means that there may be three relations, for example, A and/or B which may indicate A alone, A and B together, and B alone. In addition, the term “at least one” in this disclosure means any one of a plurality or any combination of at least two of a plurality, for example, including at least one of A, B and C may indicate including any one or more elements selected from the group consisting of A, B and C.

In addition, in order to better explain some embodiments of the present disclosure, numerous specific details are given in the following detailed description. It should be understood by those skilled in the art that some embodiments of the present disclosure can be practiced without some specific details. In some embodiments, methods, means, elements and circuits well known to those skilled in the art have not been described in detail in order to highlight the technical aspects of some embodiments of the disclosure.

The larger the change rate of AM-AM and AM-PM with the change of input signal, the worse the output signal ACLR of power amplifier. The output characteristics of the transistor voltage input signal of the power amplifier show nonlinear characteristics, in the case of large amplitude signal input (for example, a MOS transistor has a square rate relationship, a HBT follows an exponential rate relationship). The resistance of the feedback resistor in the power amplifier is a fixed resistance. Therefore, when the input power increases, the gains of the power amplifier, such as AM-AM and AM-PM, will decrease and compress, and the instability of the gains leads to the nonlinear distortion of the power amplifier.

Compensation methods for compensating a nonlinear distortion include digital compensation methods or devices such as envelope tracking and digital predistortion. However, the method or devices need the cooperation of external chips, and have high manufacturing cost and complicated control. Therefore, a compensation circuit module or gain compensation device with simple structure, easy integration in the same chip and low manufacturing cost, while giving consideration to efficiency and effectively compensating gain, is needed.

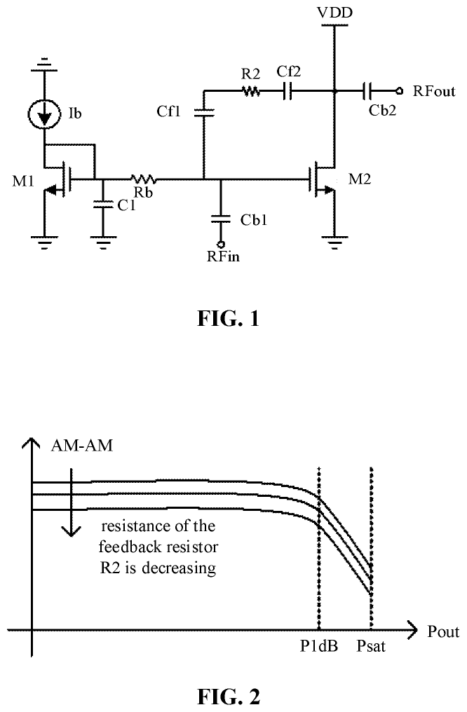

In some embodiments of this disclosure, the power amplifier circuit is shown in FIG. 1. The mirror bias circuit composed of a NMOS transistor M1, a filter capacitor C1, an isolation resistor Rb and a current source provides DC bias current to the power transistor. The DC blocking capacitors Cb1 and Cb2 are configured to feed in and feed out RF signals and isolate DC to pass RF signals. VDD is the working voltage supply terminal and provides current Id. The feedback circuit composed of DC blocking capacitors Cf1, Cf2 and a feedback resistor R2 can control the gain and stability of a transistor M2. The smaller the resistance value of the feedback resistor R2, the deeper the negative feedback, and the lower the amplifier gain. The change curve of AM-AM of the power amplifier with the feedback resistor R2 is shown in FIG. 2, in which P1dB is the gain 1 dB compression point and Psat is the saturation power of the power amplifier. The linear power of the amplifier is largely limited by the nonlinear distortion of the transistors. AM-AM slips down (that is, the gain drops greatly) and ACLR deteriorates. Under the background of multi-frequency and multi-mode mobile terminal applications, it is difficult to completely cover the working bandwidth of the power amplifier through external matching, which requires repeated iteration and compromise optimization in different frequency bands. The development efficiency is low.

Some embodiments of the disclosure provide a compensation circuit module 100. As shown in FIG. 3, the compensation circuit module 100 at least includes a variable resistor 101, a detection component 102 and a control component 103.

The detection component 102 has a detection end, which is connected with the DC blocking capacitor 201 of the power amplifier 200 and is configured to detect a voltage swing of an input signal of the DC blocking capacitor 201.

The control component 103 is connected with the detection component 102, and is configured to output a control signal according to the input signal detected by the detection component.

A variable resistor 101 is connected to the output end of the control component 103, is configured to change the resistance connected to the power amplifier 200 according to the control signal. The resistance of the variable resistor connected to the power amplifier is configured to form a feedback resistance of the power amplifier. The feedback resistance is configured to increase as gain of the power amplifier decreases. The increased feedback resistance is configured to keep the gain in a straight section of a gain change curve.

In some embodiments of the disclosure, the detection component 102 is a component capable of detecting input signals, including but not limited to a detector, a galvanometer or a power meter.

In some embodiments of the disclosure, the detection end of the detection component 102 is connected with the DC blocking capacitor 201 of the power amplifier and is configured to detect the voltage swing of the input signal passing through the DC blocking capacitor 201.

In some embodiments, the input signal refers to a radio frequency signal that can pass through the DC blocking capacitor 201. The detection end of the detection component 102 can detect the parameters of the input signal and is configured to determine whether to enable the control component 103 to output a control signal for the input signal according to parameters of the input signal.

In some embodiments of the disclosure, the parameters of the input signal acquired by the detection end of the detection component 102 include, but are not limited to, voltage parameters of the input signal, current parameters of the input signal and power parameters of the input signal.

In some embodiments of the disclosure, the control component 103 is connected with the detection component 102 and is configured to output the control signal according to the input signal detected by the detection component 102. After being connected with the detection component 102, the control component 103 receives a current or voltage signal output by the detection component 102, while the control component 103 outputs the control signal according to the current or voltage signal output by the detection component 102.

In some embodiments of the disclosure, the variable resistor 101 is connected with the control component 103, and the control signal output by the control component 103 is configured to change the resistance of the variable resistor 101.

In some embodiments, the control signal is output in the form of voltage, and the variable resistor 101 is a voltage-dependent resistor, that is, the variable resistor 101 changes with the change of the input voltage. When the control signal is output in the form of voltage, the resistance of the variable resistor 101 changes with the change of the voltage. In some embodiments, the change of the resistance of the variable resistor 101 is proportional or inversely proportional to the change of the voltage.

In some embodiments of the disclosure and in combination with FIG. 1 and FIG. 3, in the feedback circuit of the power amplifier 200, the technical solution of FIG. 1 and FIG. 3 is to set a fixed resistor R2. In this embodiment of the disclosure, the variable resistor 101 is connected to the feedback circuit and connected with the fixed resistor R2. The connection relationship between the variable resistor 101 and the fixed resistor R2 is not limited to series connection or parallel connection, may be a mixed connection of multiple variable resistors and multiple fixed resistors.

The number of variable resistors 101 may be one to more, and the number of fixed resistors R2 may be one to more. Various embodiments of the present disclosure are not limited to the illustration. As long as it is satisfied that after the variable resistor 101 is connected to the feedback circuit of the power amplifier, the resistance of the variable resistor 101 and the resistance of the fixed resistor R2 together constitute the feedback resistance of the feedback resistor of the power amplifier, and the feedback resistance is variable and the becomes larger with the increase of the power of the input signal, the way of connecting the variable resistor 101 to the power amplifier and the relationship between the variable resistor 101 and the control signal are not limited to the above embodiments.

In some embodiments, the inherent fixed resistance R2 of the power amplifier can even be directly replaced by the variable resistor 101.

In some embodiments, when the control signal is a voltage signal, and the voltage value of the control signal is inversely proportional to the power of the input signal, the feedback resistance is inversely proportional to the control signal, so that the feedback resistance is positively proportional to the power of the input signal.

In another embodiment, when the control signal is a voltage signal, and the voltage value of the control signal is positively proportional to the power of the input signal, the feedback resistance is also positively proportional to the control signal, so that the feedback resistance is also positively proportional to the power of the input signal.

In some embodiments of the disclosure, when the variable resistor 101 is a voltage-controlled resistor and the control signal output by the control component 103 is a voltage signal, the resistance of the voltage-controlled resistor and the voltage value of the control signal have a positive proportion relationship such as linear, piecewise linear, square and exponential.

In some embodiments of the disclosure, as shown in FIG. 2, after the variable resistor 101 constitutes the feedback resistance of the power amplifier 200, the gain AM-AM of the power amplifier enters the falling region due to the increase of parameters of the input radio frequency signal, such as power, so the feedback resistance of the feedback resistor is increased by the variable resistor 101, so that the gain is increased to keep in the straight section of the gain change curve.

In some embodiments of the disclosure, the compensation circuit module changes the gain by adjusting the resistance of the variable resistor. It is also possible to determine whether the control signal needs to be output by detecting the parameters of the input signal. For example, when the parameters of the input signal are lower than a threshold value, the gain itself is in a straight section, which is equivalent to the gain itself being in a stable state, it is unnecessary to output the control signal to change the resistance of the variable resistor. Only when the parameters of the input signal are higher than the threshold value and the gain is in a falling range, the control component can output the control signal to change the resistance of the variable resistor, so that the gain can be increased in the case that it is likely to decrease, and be kept in the straight section, thereby realizing the gain compensation for the power amplifier, making the input and output of the transistor of the power amplifier in a linear range, and preventing a nonlinear distortion of the power amplifier.

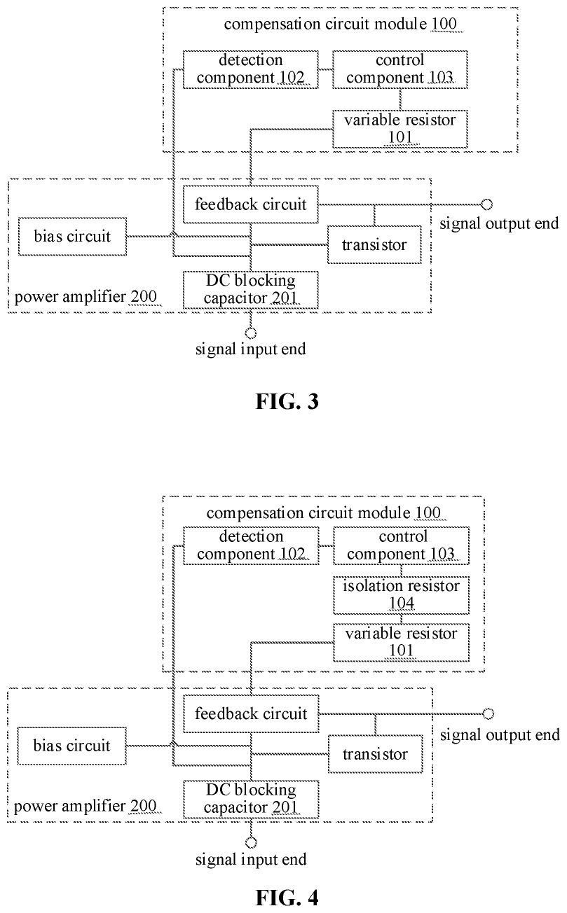

In some embodiments of the disclosure, as shown in FIG. 4, the compensation circuit module further includes an isolation resistor 104, which is connected with the output end of the control component 103 and the input end of the variable resistor 101, and is configured to change the resistance of the variable resistor 101 connected to the power amplifier 200 according to the control signal and the resistance of the isolation resistor 104.

In some embodiments of the disclosure, when the control signal output by the control component 103 is a voltage signal and the variable resistor 101 is a voltage-controlled resistor, the isolation resistor 104 is connected in series with the variable resistor 101, so as to prevent the radio frequency signal on the variable resistor 101 from leaking to the control component 103, and then change the resistance of the variable resistor 101 by changing the voltage value of the variable resistor 101.

In some embodiments of the disclosure, the control component at least includes a first sub-control component 1031 and a second sub-control component 1032, wherein the first sub-control component 1031 is connected with the detection component 102 and is configured to output a first control current proportional to the input signal according to the input signal of the DC blocking capacitor.

The second sub-control component 1032 is connected to the back end of the first sub-control component 1031 and is configured to output a current control voltage inversely proportional to the first control current according to the first control current.

In some embodiments of the disclosure, the first sub-control component 1031 is connected with the detection component 102. The first control current Ic output by the first control sub-component 1031 is proportional to the power of the input signal, and the first output current Ic may be in a linear, piecewise linear, square, exponential or other positive proportion relationship with the input power Pin.

In some embodiments of the disclosure, the second sub-control component 1032 is connected with the back end of the first sub-control component 1031, and is configured to output the current control voltage Vc inversely proportional to the first control current Ic according to the first control current Ic.

In some embodiments of the disclosure, the first sub-control component 1031 is also connected with a first control voltage source, and is configured to receive a voltage Vcon1 output by the first control voltage source. A power threshold Poffset of the input power Pin is determined based on the voltage Vcon1 output by the first control voltage source. The larger Vcon1 is, the lower the power threshold Poffset is, and the lower the power starting point Poffset at which the detection component 102 starts to detect the input signal, so that the input signal can be detected as early as possible and the cases of the premature decrease of the power amplifier can be reduced.

In some embodiments, the second sub-control component 1032 can be a programmable current control voltage source, by which the flow control voltage Vc and the first control current Ic can be in a decreasing function relationship, and Vc and Ic can be in an inverse proportional relationship such as linear, piecewise linear, square, exponential, etc. Take the linear relationship as an example, the proportional coefficient is adjustable with programming by the second control voltage Vcon2, and the upper limit of the flow control voltage Vc is limited by the voltage source Vlimit, realizing the decreasing function of Vc with the input signal Ic.

In some embodiments of the disclosure, by the first sub-control component 1031, the output of the first control current IC can be determined based on the parameters of the input signal. By the second sub-control component 1032, based on the first control current Ic, a current control voltage Vc inversely proportional to the first control current Ic can be output. The current control voltage Vc can adjust the resistance of the variable resistor 101 when the variable resistor 101 is a voltage-controlled resistor, so as to adjust the gain of the power amplifier.

In some embodiments of the disclosure, as shown in FIG. 6, the detector includes the detection component and the first sub-control component.

The detection component of the detector is configured to detect the voltage swing of the input signal passing through the DC blocking capacitor.

The detector is connected with the first control power supply to form the first sub-control component, and the first control power supply is configured to generate the first control voltage. The detector is further configured to determine the power threshold according to the first control voltage. According to the power threshold, the voltage swing that meets the preset conditions is determined. According to the voltage swing that meets the preset conditions, the first control current is output.

In some embodiments of the disclosure, the detection component of the detector detects the input signal passing through the DC blocking capacitor, determines the voltage swing of the input signal, and determines the power value Pin according to the voltage swing, that is, obtains the input power value Pin of the power amplifier.

In some embodiments of the disclosure, the input signal is a radio frequency signal.

In this embodiments of the disclosure, as for the detector detecting the input signal as a radio frequency signal, a radio frequency detector (RF detector) can be selected, which includes but is not limited to a zero-bias Schottky diode detector, a bias Schottky diode detector, a logarithmic detector, etc.

In some embodiments of the disclosure, the RF detector can accurately detect and measure the amplitude and power of the RF signal. When the RF detector detects the RF signal, the RF detector outputs a voltage value. The voltage value is proportional to the power of the input signal and the output voltage value can correspond to the input power value.

In some embodiments, when the RF detector detects the voltage swing U of the RF signal passing through the DC blocking capacitor and the node resistance is R, the corresponding power value of the input RF signal can be calculated according to a formula.

In some embodiments of the disclosure, the detector is also connected with a logic controller and/or an intelligent terminal with the function of executing the judgment step, including but not limited to: a logic controller such as a controller, a single chip microcomputer, and/or an intelligent terminal such as a smart phone or a computer. The logic controller and/or the intelligent terminal can acquire the voltage swing of the input signal determined by the detector, determine the power Pin of the input signal according to the voltage swing, and determine the first control voltage Vcon1 generated by the first control power supply connected to the detector according to the power Pin of the input signal. The larger the value of the first control voltage Vcon1 is, the lower the power threshold Poffset determined by the logic controller and/or the intelligent terminal is. The logic controller and/or intelligent terminal compares the power Pin of the input signal with the power threshold Poffset according to the acquired power Pin of the input signal determined by the detector. When the power Pin of the input signal is higher than the power threshold Poffset, it is determined that the input signal meets the preset conditions. The logic controller and/or the intelligent terminal can control the detector to output the first control current Ic.

In some embodiments of the disclosure, the logic controller and/or the intelligent terminal can acquire the power of the input signal through the detector, and determine the power threshold Poffset by setting different first control voltages Vcon1.

In some embodiments, different first control voltages Vcon1 can also be determined by a user or a designer through a logic controller and/or an intelligent terminal according to personal experience.

In some embodiments, the controller may automatically determine the corresponding first control voltage Vcon1, according to the obtained power value in the case of the gain drop point of the power amplifier.

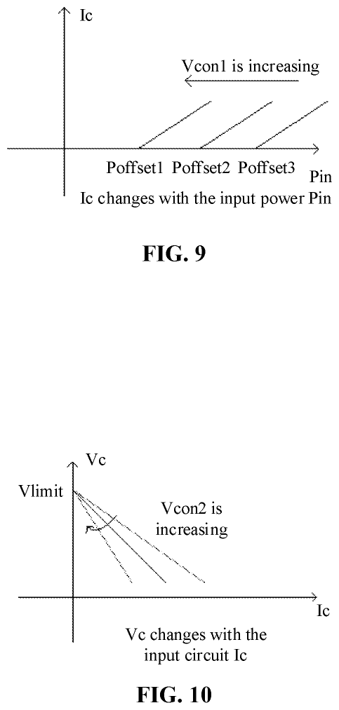

In some embodiments of the disclosure, the relationship between the first control current Ic and the input power Pin, as well as the power threshold Poffset and the first control voltage Vcon1, can be shown as FIG. 9. The larger the first control voltage Vcon1, the smaller the power threshold Poffset, such as Poffset1<Poffset2<Poffset3. Starting from the power threshold Poffset, the output first control current Ic increases as the input power Pin.

In some embodiments of the disclosure, by setting the first control voltage Vcon1, the power threshold Poffset is determined, and then in the process of increasing of the input power of the input signal, it is determined to compensate the gain in the case of determining how much the input power is increased. It is unnecessary to compensate the gain all the time. Only when the gain is large enough, it is determined to compensate the gain of the power amplifier. In this way, the resources for calculation or control can be saved, and the gain can be accurately compensated. Furthermore, the circuits shown in FIGS. 3, 4, 5 and 6 are simple in structure and easy to be integrated in a chip.

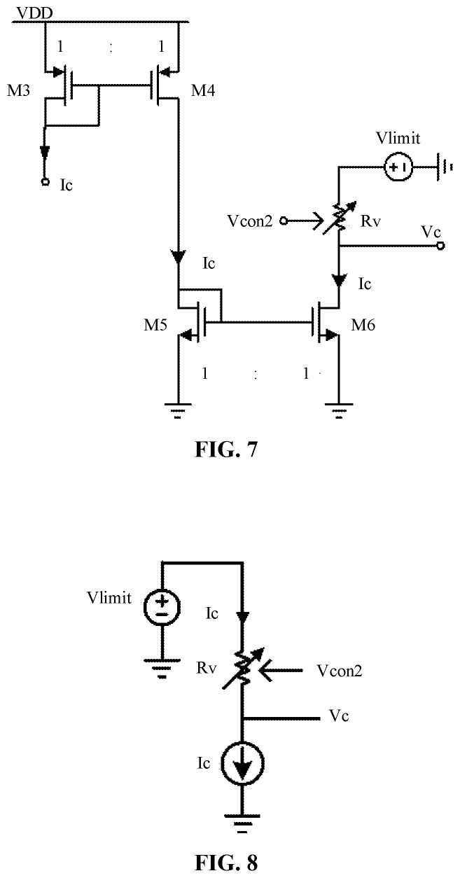

In some embodiments of the disclosure combination with FIG. 7 and FIG. 8, the second sub-control component 1032 at least includes a voltage source Vlimit, a voltage-controlled resistor Rv, a second control power supply and a current mirror.

The current mirror is connected with the voltage-controlled resistor, and is configured to receive the first control current and mirror the first control current to the voltage-controlled resistor.

The voltage-controlled resistor is connected with the second control power supply, and the second control power supply outputs a second control voltage. The second control voltage is configured to control the resistance of the voltage-controlled resistor.

The output end of the current control voltage is arranged between the voltage-controlled resistor and the current mirror, and is configured to output the current control voltage. The voltage value of the current control voltage is equal to the voltage value of the voltage source minus the product of the voltage-controlled resistor and the first control current.

In some embodiments of the disclosure, the current mirror is a 1:1 current mirror composed of transistor M3 and transistor M4, transistor M5 and transistor M6. The transistor M3 receives the first control current Ic, and the first control current is mirrored to the voltage-controlled resistor Rv through the current mirror. The second control power supply is connected with the voltage-controlled resistor Rv, and the second control voltage Vcon2 output by the second control power supply is configured to control the resistance of the voltage-controlled resistor Rv.

In some embodiments of the disclosure, the calculation formula of the current control voltage is as follows:

Vc=Vlimit−Rv*Ic, Formula 1

Vc is the current control voltage value. The upper limit of the output voltage of Vc is limited by the voltage Vlimit output by the voltage source. The relationship between the second control voltage Vcon2 and the voltage-controlled resistor Rv is a positive proportion relationship. When Vcon2 is larger, the resistance of the voltage-controlled resistor Rv connected to the circuit is larger. The simplified equivalent circuit is shown in FIG. 8.

In some embodiments of the disclosure combination with FIG. 10, in formula 1, the relationship between Vcon2 and voltage-controlled resistor Rv is a positive proportion relationship, so Vcon2 can control the relation between Vc and Ic, and further control how much the resistance of the variable resistor 101 changes with the input power.

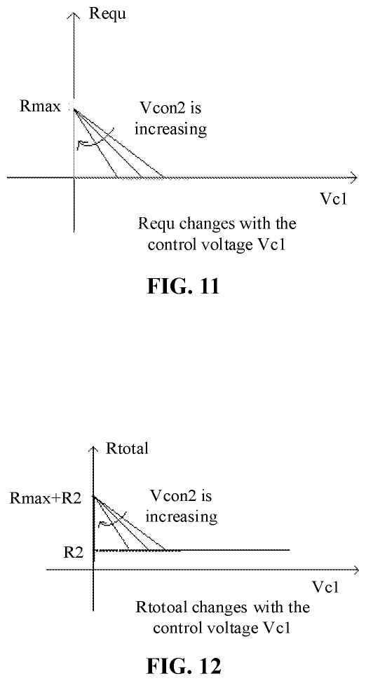

In some embodiments of the disclosure, the relationship of the equivalent resistance Requ of the variable resistor 101, and the current control voltage Vc can be an inverse proportion relationship such as linear, square and exponential. Taking the linear relationship as an example, it is realized that the equivalent resistance Requ varies with the change of the resistance control voltage Vc1, as shown in FIG. 11.

In some embodiments of the disclosure, after the variable resistor 101 controlled by the compensation circuit assembly 100, that is, D1, is connected to the feedback circuit of the power amplifier 200, the feedback resistance can be expressed as follows:

Rtotal=R2+Requ, Formula 2

In the above formula, R2 is a fixed resistance, and the unit magnitude is about one hundred of ohms. In this way, under the condition of low power input, it is to avoid that the equivalent resistance of D1 is too small, leading to too deep feedback and too low gain of a low power signal. The curve of the resistance of Rtotal with the resistance control voltage Vc1 is shown in FIG. 12.

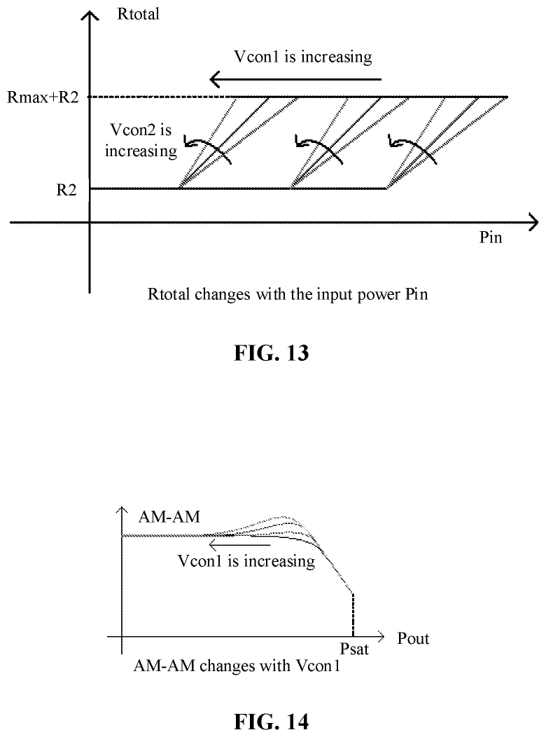

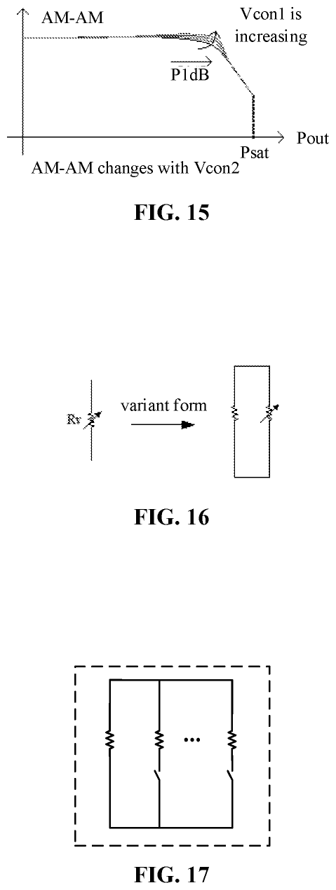

In some embodiments of the disclosure, combining the above-mentioned embodiments with FIGS. 9, 10, 11 and 12, FIG. 9 shows that the first control current Ic output by the first sub-control component 1031 is proportional to the power of the input signal, FIG. 10 shows that the control signal of the second sub-control component 1032, such as the current control voltage Vc, is inversely proportional to the first control current Ic, and FIG. 11 shows that the equivalent resistance Requ of variable resistor 101 decreases with the increase of voltage Vc1 when the resistance control voltage Vc1 is output after current control voltage Vc is divided by the isolation resistor 104. FIG. 12 shows that the feedback resistance Rtotal=R2+Requ decreases with the increase of voltage Vc1, from R2+Rmax to R2. In this way, the relationship between the feedback resistance Rtotal and the input power Pin is shown in FIG. 13, and the improvement effects of AM-AM curve of the first control voltage Vcon1 and the second control voltage Vcon2 are shown in FIGS. 14 and 15. Vcon1 is configured to determine the starting power point Poffset of compensation gain, and Vcon2 is configured to control how much the feedback depth decreases with the input power, and Vcon1 and Vcon2 are controlled by a wired or wireless external control device with executable logic, such as a single chip microcomputer, or an intelligent terminal with controller and communication function. By programming with an intelligent terminal or a logic control device, and the specific adjustment is made according to AMAM curves of different frequency points, in a wide working frequency band, the power amplifier can meet better ACLR requirements. Furthermore, gain compensation of gain change curves in different frequency points is realized. Under the condition that the gain is expected to decrease, the gain is increased by increasing the feedback resistance, so that the increased gain is kept in the straight section of the gain change curve, thus ensuring the linearity of the power amplifier and delaying the linear distortion of the power amplifier.

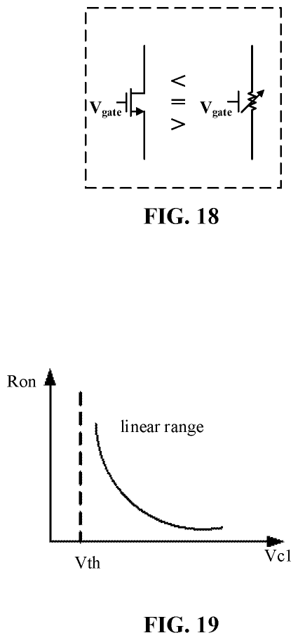

In some embodiments of the disclosure, the structure of the variable resistor includes, but is not limited to the following three: the parallel connection of a fixed resistor with one or more voltage-controlled variable resistors as shown in FIG. 16, the parallel connection of a fixed resistor with one or more circuits including switches and fixed resistors as shown in FIG. 17, the parallel connection of a transistor with a fixed resistor as shown in FIG. 18.

In some embodiments of the disclosure, as for the variable resistance structure composed of a transistor and a fixed resistor in parallel as shown in FIG. 18, when working in the linear region of the transistor as shown in FIG. 19, the equivalent resistance Ron decreases as the voltage increases from Vth. The equivalent resistance is linearly inversely proportional to the voltage Vc1.

In some embodiments of the disclosure, the structure of the variable resistor is not limited to the above-mentioned embodiments, and any series or parallel structure for realizing the variable resistor is within the implementation scope of some embodiments of the disclosure.

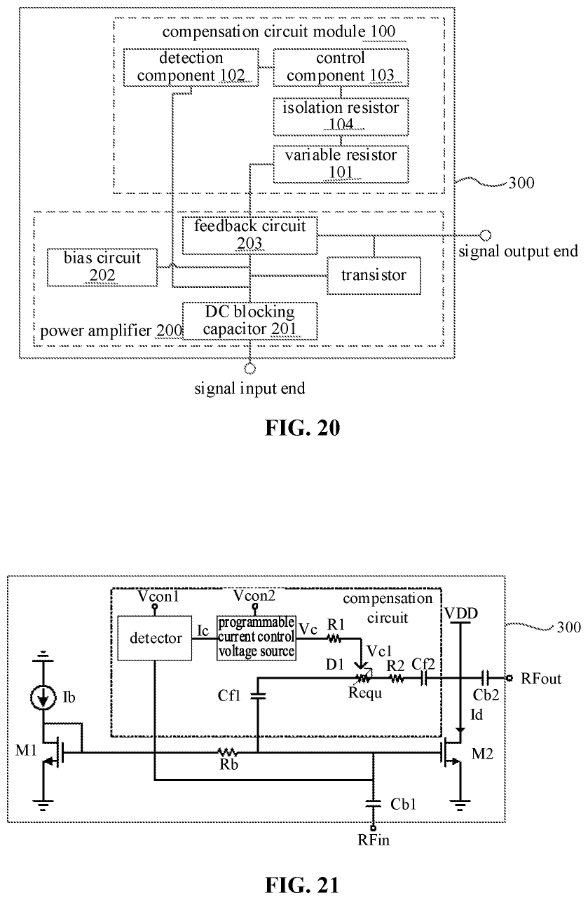

In combination with FIG. 20 and FIG. 21, some embodiments of the disclosure provide a power amplification assembly 300, which includes a power amplifier 200 and the compensation circuit module 100 in the previous embodiment. The power amplifier 200 at least includes a DC blocking capacitor Cb1 arranged at the signal input end, a transistor M2, a bias circuit 202, a feedback circuit 203 and a DC blocking capacitor Cb2 arranged at the signal output end.

The first end of the feedback circuit 203 is connected to the DC blocking capacitor 201 at the signal input end, the bias circuit 202 and the gate of the transistor M2. The second end of the feedback circuit 203 is connected to the DC blocking capacitor Cb2 at the signal output end and the drain of the transistor M2. The feedback resistor of the feedback circuit 203 at least includes a fixed resistor and the variable resistor 101 connected to the feedback circuit 203, and the fixed resistor R2 and the variable resistor 101 are configured to constitute the feedback resistance of the power amplifier 200. The feedback resistance is configured to increase when the gain of the power amplifier decreases. The increased feedback resistance is configured to keep the gain in the straight section of the gain change curve.

In some embodiments of the disclosure, the compensation circuit component 100 is configured to compensate the gain of the power amplifier 200. The compensation resistor assembly 100 is configured to change the feedback resistance in the feedback circuit of the power amplifier according to the input signal of the power amplifier 200. In the case that the gain of the power amplifier is greatly decreased due to a large increase in power, the feedback resistance increases, and the increased feedback resistance is configured to keep the gain in a straight section of the gain change curve, as shown in FIGS. 14 and 15.

In some embodiments of the disclosure, in the power amplifier, the bias circuit 202 includes a NMOS transistor M1, a current source Ib and an isolation resistor Rb. Rb is configured to provide a bias current to the transistor M2. The feedback circuit is connected with the signal output end RFout and the signal input end RFin of the power amplifier and is configured to provide feedback resistance to the power amplifier to compensate the gain of the power amplifier. The feedback resistance constituted by the variable resistor 101 can dynamically compensate the gain of the power amplifier.

In some embodiments of the disclosure, the DC blocking capacitors Cb1 and Cb2 are configured to feed in and feed out RF signals, and to isolate DC and pass RF signals. The DC blocking capacitors Cf1, Cf2, the feedback resistor R2 and the feedback circuit composed of the variable resistor D1 and the fixed resistor R2 controlled by the compensation resistor assembly 100 realize the control of the gain and stability of the transistor M2. The variable resistor D1 and the fixed resistor R2 constitute the feedback resistor. The larger the feedback resistor, the shallower the negative feedback, and the lower the gain of the power amplifier.

In some embodiments of the disclosure, the power amplifier can change the gain by adjusting the resistance of the variable resistor in the preset communication frequency band. It is also possible to determine whether the control signal needs to be output by detecting the parameters of the input signal. For example, if the parameters of the input signal are lower than the threshold value, the gain itself is in the straight section and at a stable value, it is unnecessary to output the control signal to change the resistance of the variable resistor. Only when the parameters of the input signal are higher than the threshold and the gain is in a falling range, by the control component outputting the control signal, the resistance of the variable resistor is changed, so that the gain can be increased in the case of a possible falling to keep in the straight section, and thus gain compensation of the power amplifier is achieved, making the input and output of the transistor of the power amplifier in a linear range, and preventing a nonlinear distortion of the power amplifier.

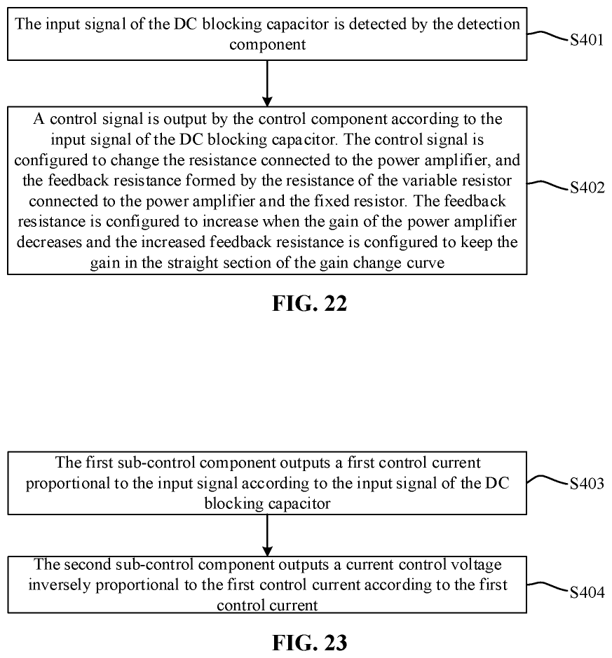

In combination with FIG. 22, some embodiments of this disclosure provide a compensation method, which uses the above compensation circuit module to compensate the gain of the power amplifier. The method includes the following operations.

In S401, an input signal of the DC blocking capacitor is detected by the detection component.

In S402, a control signal is output by the control component according to the input signal of the DC blocking capacitor. The control signal is configured to change the resistance connected to the power amplifier, and the feedback resistance constituted by the resistance of the variable resistor connected to the power amplifier and the fixed resistor. The feedback resistance is configured to increase when the gain of the power amplifier decreases and the increased feedback resistance is configured to keep the gain in the straight section of the gain change curve.

In some embodiments of the disclosure, the executing body of the compensation method can be the operation of executing the compensation method by a logic controller or an intelligent terminal which can be electrically or communicatively connected with the power amplifier, executing the operations of the compensation method. The logic control device can be, but not limited to, a single chip microcomputer and a controller. The intelligent terminal can be, but not limited to, a smart phone and a computer. The operations of the compensation method are executed by means of programming control. In some embodiments of the disclosure, in S401, the parameters of the input signal of the DC blocking capacitor are detected by the detection component, including but not limited to current parameters, voltage parameters and time period of the input signal. The logic controller or the intelligent terminal calls the parameters of the input signal detected by the detection component, to calculate and determine the power of the input signal.

In some embodiments of the disclosure, in S402, the logic controller or the intelligent terminal outputs a control signal according to the input signal of the DC blocking capacitor through the control component, and the control signal is configured to change the resistance of the variable resistor 101, thereby changing the gain of the power amplifier, so that the gain of the power amplifier is kept in the straight section of the gain change curve.

In some embodiments of the disclosure, the parameters of the input signal are obtained by controlling the detection component of the compensation circuit module, and then the control component of the compensation circuit module is controlled to output a control signal to the variable resistor 101 according to the input signal, thereby controlling the resistance of the variable resistor.

In some embodiments of the disclosure, by changing the resistance of the variable resistor, the gain is stabilized in the straight section of the gain change curve, and the gain compensation of the power amplifier is realized, so that the input and output of the transistors of the power amplifier are in a linear range, thereby preventing the linear distortion of the power amplifier.

In some embodiments of the disclosure, in combination with FIG. 23, the method further includes the following operations.

In S403, the first sub-control component outputs a first control current proportional to the input signal according to the input signal of the DC blocking capacitor.

In S404, the second sub-control component outputs a current control voltage inversely proportional to the first control current according to the first control current.

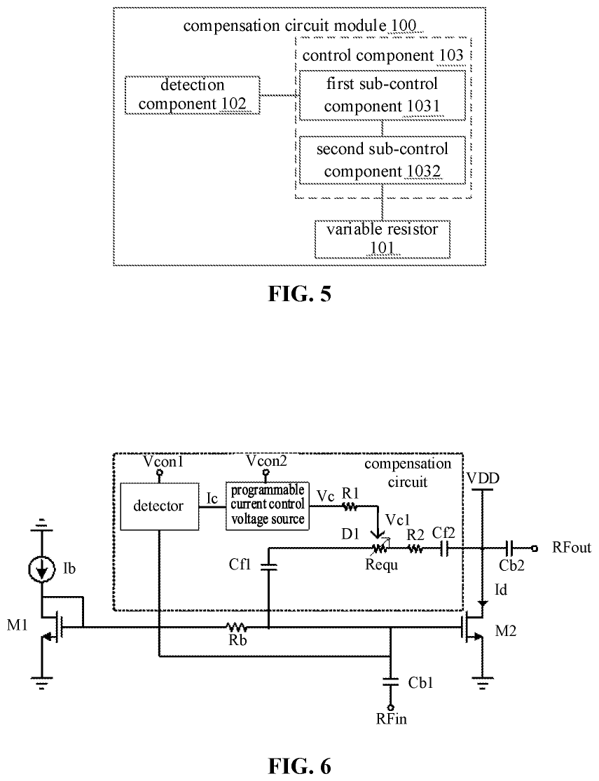

In some embodiments of the disclosure, in combination with FIG. 3, FIG. 5, FIG. 6 and FIG. 23, in S403, the first sub-control component 1031 outputs the control current Ic proportional to the power of the input signal according to the input signal input by the DC blocking capacitor 201, and the first output current Ic can have a linear, piecewise linear, square, exponential and other positive proportion relationship with the input power Pin.

In some embodiments of the disclosure, the second sub-control component 1032 is configured to output the current control voltage Vc inversely proportional to the first control current Ic according to the first control current Ic.

In some embodiments of the disclosure, the first sub-control component 1031 is connected with the first control voltage source, and is configured to receive the voltage Vcon1 output by the first control voltage source, and determine the power threshold Poffset of the input power Pin based on the voltage Vcon1 output by the first control voltage source. The larger Vcon1, the lower the power threshold Poffset, and the lower the starting point Poffset at which the detection component 102 starts to detect the power of the input signal, so that the input signal can be detected as early as possible and the premature decrease of the power amplifier can be avoided.

In some embodiments of the disclosure, the logic controller or intelligent terminal is connected with the first control voltage source of the compensation circuit module 100 to control the voltage Vcon1 output by the first control voltage source, and determine the relationship between the Vcon1 and the power threshold Poffset. The larger Vcon1 is, the lower the power threshold Poffset is. Therefore, the input signal can be detected as early as possible to avoid the premature decrease of the power amplifier.

In some embodiments of the disclosure, the second sub-control component 1032 can be a programmable current control voltage source, by which the current control voltage Vc and the first control current Ic can be in a decreasing function relationship, and Vc and Ic may be in an inverse proportion relationship such as linear, piecewise linear, square, exponential, etc. Take the linear relationship as an example, the proportional coefficient is adjustable with programming by the second control voltage Vcon2, and the upper limit of the current control voltage Vc is limited by the voltage source Vlimit, realizing the decreasing function relationship between Vc and the input signal Ic.

In some embodiments of the disclosure, the logic controller or intelligent terminal is connected with the second control voltage source of the compensation circuit module, and is configured to control the second control voltage source to output the second control voltage Vcon2 to the second sub-control component. The second control voltage Vcon2 is configured to control the current control voltage output by the second sub-control component control subassembly.

In some embodiments of the disclosure, by the first sub-control component 1031, the output of the first control current IC can be determined according to the parameters of the input signal. By the second sub-control component 1032, according to the first control current Ic, the current control voltage Vc inversely proportional to the first control current Ic can be output. The current control voltage Vc can adjust the resistance of the variable resistor 101 when it is a voltage-controlled resistor, so as to adjust the gain of the power amplifier.

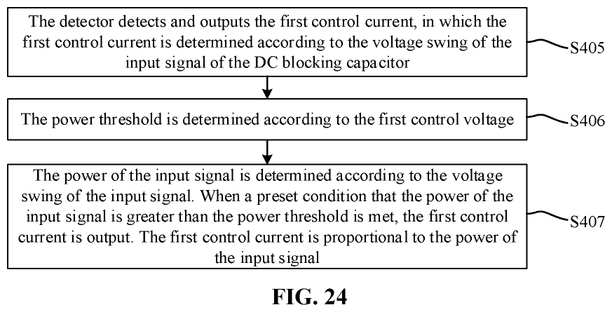

In some embodiments of the disclosure, with reference to FIG. 24, the method further includes the following operations

In S405, the detector detects and outputs the first control current, in which the first control current is determined according to the voltage swing of the input signal of the DC blocking capacitor.

In S406, the power threshold is determined according to the first control voltage.

In S407, the power of the input signal is determined according to the voltage swing of the input signal. When a preset condition that the power of the input signal is greater than the power threshold is met, the first control current is output. The first control current is proportional to the power of the input signal.

In some embodiments of the disclosure, the detection component of the detector detects the voltage swing of the input signal passing through the DC blocking capacitor, and determines the power value Pin of the input signal according to the voltage swing, that is, obtains the input power value Pin of the power amplifier.

In some embodiments of the disclosure, the detector is also connected with a logic controller and/or an intelligent terminal with the function of executing the judgment step, including but not limited to: a logic controller such as a controller, a single chip microcomputer, and/or an intelligent terminal such as a smart phone or a computer. The logic controller and/or the intelligent terminal can acquire the voltage swing of the input signal determined by the detector, determine the power Pin of the input signal according to the voltage swing, and determine the first control voltage Vcon1 generated by the first control power supply connected with the detector according to the power Pin of the input signal. The larger the value of the first control voltage Vcon1 is, the lower the power threshold Poffset determined by the logic controller and/or the intelligent terminal is. The logic controller and/or intelligent terminal compares the power Pin of the input signal with the power threshold Poffset according to the acquired power Pin of the input signal determined by the detector. When the power Pin of the input signal is higher than the power threshold Poffset, it is determined that the input signal meets the preset conditions. The logic controller and/or the intelligent terminal can control the detector to output the first control current Ic.

In some embodiments of the disclosure, the logic controller and/or the intelligent terminal can acquire the power of the input signal through the detector, and determine the power threshold Poffset by setting different first control voltages Vcon1.

In some embodiments, different first control voltages Vcon1 can also be determined by a user or a designer through a logic controller and/or an intelligent terminal according to personal experience.

In some embodiments of the disclosure, the relationship between the first control current Ic and the input power Pin, as well as the power threshold Poffset and the first control voltage Vcon1, can be shown as FIG. 9. The larger the first control voltage Vcon1, the smaller the power threshold Poffset, such as Poffset1<Poffset2<Poffset3. The output first control current Ic increases as the input power Pin increases from the power threshold Poffset.

In some embodiments of the disclosure, by setting the first control voltage Vcon1, the power threshold Poffset is determined, and then in the process of increasing the input power of the input signal, it is determined to compensate the gain at how much the input power is increased. In this way, It is unnecessary to compensate the gain all the time. Only when the gain is large enough, it is determined to compensate the gain of the power amplifier. In this way, the resources for calculation or control can be saved, and the gain can be accurately compensated.

In some embodiments of the disclosure, the method further includes the following operations.

The current mirror receives the first control current and mirrors the first control current to the voltage-controlled resistor;

The second control power supply outputs a second control voltage, in which the second control voltage is configured to control the resistance of the voltage-controlled resistor.

The output end of the current control voltage is arranged between the voltage-controlled resistor and the current mirror and outputs the current control voltage, in which the voltage value of the current control voltage is equal to the voltage value of the voltage source minus the product of the voltage-controlled resistor and the first control current.

The current mirror is a 1:1 current mirror composed of transistor M3 and transistor M4, transistor M5 and transistor M6. The transistor M3 receives the first control current Ic, and the first control current is mirrored to the voltage-controlled resistor Rv by the current mirror. The second control power supply is connected with the voltage-controlled resistor Rv, and the second control voltage Vcon2 output by the second control power supply is configured to control the resistance of the voltage-controlled resistor Rv.

In some embodiments of the disclosure, in Formula 1, the upper limit of the output voltage of Vc is limited by the voltage Vlimit output by the voltage source. The relationship between the second control voltage Vcon2 and the voltage-controlled resistor Rv is a positive proportion relationship. When Vcon2 is larger, the resistance of the voltage-controlled resistor Rv connected to the circuit is larger. The simplified equivalent circuit is shown in FIG. 8.

In some embodiments of the disclosure, as shown in FIG. 10, in formula 1, the relationship between Vcon2 and voltage-controlled resistor Rv is a positive proportion relationship, so Vcon2 can control the proportion relation between Vc and Ic, and further control how much the resistance of the variable resistor 101 changes with the input power.

In some embodiments of the disclosure, the relationship of the equivalent resistance Requ of the variable resistor 101 and the current control voltage Vc, can be a inversely proportion relationship such as linear, square and exponential. Taking the linear relationship as an example, it is realized that the equivalent resistance Requ varies with the change of the resistance control voltage Vc1, as shown in FIG. 11.

In some embodiments of the disclosure, after the variable resistor 101 controlled by the compensation circuit assembly 100, that is, D1, is connected to the feedback circuit of the power amplifier 200, the feedback resistance can be expressed as Rtotal=R2+Requ, in which R2 is a fixed resistance, and the unit is on the order of one hundred of ohms. In this way, under the condition of low power input, it is to avoid that the equivalent resistance of D1 is too small and leads to too deep feedback and too low gain of a low power signal. The curve of the resistance Rtotal with the resistance control voltage Vc1 is shown in FIG. 12.

In some embodiments of the disclosure, combining the above-mentioned embodiments with FIGS. 9, 10, 11 and 12, FIG. 9 shows that the first control current Ic output by the first sub-control component 1031 is proportional to the power of the input signal, FIG. 10 shows that the control signal of the second sub-control component 1032, such as the current control voltage Vc, is inversely proportional to the first control current Ic, and FIG. 11 shows that the current control voltage Vc divided through the isolation resistor 104, outputs a resistance control voltage Vc1, and the equivalent resistance Requ of variable resistor 101 decreases with the increase of voltage Vc1. FIG. 12 shows that the feedback resistance Rtotal=R2+Requ decreases with the increase of voltage Vc1, from R2+Rmax to R2. In this way, the relationship between the feedback resistance Rtotal and the input power Pin can be made as shown in FIG. 13, and the improvement effects of AM-AM curve for the first control voltage Vcon1 and the second control voltage Vcon2 are shown in FIGS. 14 and 15. Vcon1 is configured to determine the starting power point Poffset of compensating the gain, and Vcon2 is configured to control how much the feedback depth decreases with the input power, and Vcon1 and Vcon2 are controlled by a wired or wireless external control device with executable logic, such as a single chip microcomputer, or an intelligent terminal with controller and communication function. By programming with an intelligent terminal or a logic control device, and targetedly adjusting Vcon1 and Vcon2 according to AMAM curves of different frequency points, in a wide working frequency band, the power amplifier can meet better ACLR requirements. Furthermore, gain compensation of gain change curves in different frequency points is realized. Under the condition that the gain is expected to decrease, the gain is increased by increasing the feedback resistance, so that the increased gain is kept in the straight section of the gain change curve, thereby ensuring the linearity of the power amplifier and delaying the linear distortion of the power amplifier.

In some embodiments of the disclosure, in a mobile communication system, the efficiency and linear power of a front-end power amplifier directly affect the energy consumption and communication quality of a base station and a mobile terminal, and the output power of the uplink modulated signal of the terminal device amplified by the front-end power amplifier and the index of adjacent channel leakage ratio (ACLR) must meet the requirements of various mobile communication protocols. In a memoryless system, the ACLR performance of a power amplifier can be characterized by amplitude modulation to amplitude modulation distortion (AM-AM) and amplitude modulation to phase modulation distortion (AM-PM). The larger the change rate of AM-AM and AM-PM with the input signal, the worse the output signal ACLR of the amplifier. The main source of AM-AM distortion is that the output characteristics of the transistor voltage input signal of the power amplifier show nonlinear characteristics in the case of large amplitude signal input (such as the square rate relationship of MOS transistor and the exponential rate relationship of HBT transistor). With increase of an input driving power, the power amplifier experiences gain compression, leading to spectrum diffusion and ACLR deterioration.

In some embodiments of the disclosure, when designing the amplifier, the difference between a linear power (undistorted or weakly distorted power) and the saturated power of a power amplifier is usually determined according to the value of the non-constant envelope modulation signal PAR (the ratio of peak power with a probability of 0.01% to the total average power) adopted by the communication system. A selection of the difference value needs to make a compromise between ACLR performance and efficiency of power amplifier. When the value is too large, it is generally necessary to reduce the load impedance of the amplifier. The output signal ACLR can meet the protocol requirements, but the amplifier has high working current and low efficiency. When the value is too small, the load impedance of the amplifier may be increased and the current consumed by the amplifier can be reduced. However, the premature gain compression leads to the distortion of part of signals higher than the average power, and the ACLR performance cannot meet the protocol requirements.

In some embodiments of the disclosure, there are many ways to reduce the influence of power amplifier gain compression on the output signal ACLR while giving consideration to the efficiency. Digital compensation methods such as envelope tracking and digital predistortion, have good effects, but need the cooperation of external chips and have high cost and complicated control. It is also possible to add an AM-AM compensation circuit in the amplifier link. As the amplitude of the input signal becomes larger, the bias current (voltage) of the amplifier is increased to compensate for the compression of AM-AM. The circuit is relatively simple, with good effect, easy integration and low cost.

In some embodiments of the disclosure, the common power amplifier circuit is shown in FIG. 1. The mirror bias circuit composed of a NMOS transistor M1, a filter capacitor C1, an isolation resistor Rb and a current source Ib provides DC bias current to the power transistor. The DC blocking capacitors Cb1 and Cb2 are configured to feed in and out RF signals, and also are configured to isolate DC. The feedback network composed of DC blocking capacitors Cf1, Cf2 and feedback resistor R2 can control the gain and stability of power transistor M2. The smaller the value of feedback resistor R2, the deeper the negative feedback, and the lower the amplifier gain. The curve of the amplifier AM-AM with the feedback resistor R2 is shown in FIG. 2, in which P1dB is the gain 1 dB compression point and Psat is the saturation power of the amplifier. The linear power of the amplifier is largely limited by the non-linear distortion of the amplifier device. With the increase of the output power Pout of the amplifier, AM-AM slips down and ACLR deteriorates. Under the background of multi-frequency and multi-mode mobile terminal applications, it is difficult to completely cover the working bandwidth of the amplifier through external matching, which requires repeated iteration and compromise optimization in different frequency bands, and the development efficiency is low.

In some embodiments of the disclosure, the example provides an AM-AM compensation circuit based on a variable resistor, a detector and a programmable current control voltage source. It is achieved that the power point at which AM-AM compensation is started and the change rate of AM-AM with input signal can be programmed, and can be freely adjusted according to the actual circuit state, thereby shortening the development period. Optimization may be done at different frequency points, and the power amplifier can obtain better ACLR in the whole frequency band. As shown in FIG. 3, the compensation circuit consists of the following three parts.

The first part is a detector, in which the detector provides the output current Ic change with input power after the input power exceeds a specific value (Poffset). The output current Ic can have a positive proportion relationship, such linear, piecewise linear, square and exponential relationship, with the input power Pin. Taking the linear relationship as an example, the Poffset value is controlled by the voltage Vcon1 of the detector, and determines the power point at which AM-AM compensation is started. The larger the voltage Vcon1, the lower power threshold of the detector is as shown in FIG. 9.

The first part is the programmable current control voltage source that makes the output voltage Vc and the input signal Ic in a decreasing function, Vc and Ic can be linear, piecewise linear, square, exponential and other inverse proportional relationships. Take the linear relationship as an example, the proportional coefficient can be adjusted with programming by the voltage Vcon2, and the upper limit of the output voltage of Vc is limited by Vlimit, which can realize the control mode of Vc with the input signal Ic as shown in FIG. 11. FIG. 7 shows an implementation of the circuit, in which M3 and M4, M5 and M6 form a 1:1 current mirror, and voltage Vcon2 controls the voltage-controlled variable resistor Rv. The larger Vcon2 is, the larger the resistance of the voltage-controlled variable resistor is. The simplified equivalent circuit is shown in FIG. 8. The output voltage value is the Vc value calculated by formula 1, and there are different RVs under different Vcon2, realizing the variable proportional relationship between Vc and Ic.

The first part is used as a voltage-controlled variable resistor D1, the control voltage Vc1 is provided by a programmable current control voltage source Vc through an isolation resistor R1. The D1 equivalent resistance, Requ, may be linear, piecewise linear, square, exponential and other inverse proportion relationships with the control voltage Vc1. Taking the linear relationship as an example, the programming controllability of the equivalent resistance Requ with the control voltage Vc1 is realized, as shown in FIG. 12.

In some embodiments of the disclosure, in FIG. 6 after the voltage-controlled variable resistor D1 is connected in series in the power amplifier feedback network, the total feedback resistance can be expressed as Rtotal=R2+Requ, in which R2 is a fixed resistor with the unit on the order of about one hundred of ohms, so as to avoid that the equivalent resistance Requ of D1 is too small, the feedback is too deep and the small signal gain is too low in case of low power input. The variation curve of Rtotal resistance with control voltage Vc1 is shown in FIG. 13. When the amplitude of the input signal exceeds the detection threshold set by Vcon1, the detector starts to output a current Ic proportional to Pin. The current enters the programmable current control voltage source set by Vcon2 and is converted into a control voltage. The feedback resistor Rtotal becomes a non-zero value with Requ, the feedback depth reduces and the amplifier gain is high. As the input signal exceeds the threshold power, the value of Rtotal becomes larger, the feedback depth is shallower, and the amplifier gain is higher, so that the feedback depth becomes shallower with the input power input, and the AMAM slip caused by the nonlinear distortion of the power amplifier transistor at high power is compensated, which can improve ACLR. The relationship between Rtotal and the input power Pin is shown in FIG. 13. The improvement effect of AMAM curve by adjusting control voltages Vcon1 and Vcon2 is shown in FIGS. 14 and 15. Vcon1 can control the input power point at which the feedback takes effect, Vcon2 can control how much the feedback depth decreases with input power. The programming is flexible and the adjustment can be made. according to the AMAM curves of different frequency points. The amplifier can meet better ACLR requirements in a wide working frequency band.

Based on the compensation circuits and the compensation methods provided by the examples or embodiments of the disclosure, the circuit can be implemented relatively simple and the design is flexible. By adjusting the parameters of the compensation circuit, the power point at which AM-AM compensation is started and AM-AM compensation amplitude can be adjustable with programming, with high degree of freedom, good applicability, widening the working bandwidth of the amplifier. The integration is easy and the cost is low.

In some embodiments of the disclosure, a device is provided and the device includes a processor and a memory.

The memory is configured to store processor executable instructions;

The processor is configured to implement the operations of the compensation method described above when the computer service is run.

It can be understood by those skilled in the art that all or part of the operations of realizing the above-mentioned method embodiments can be accomplished by hardware related to program instructions, and the above-mentioned program can be stored in a computer-readable storage medium, and the program, when executed, can perform the operations included in the above-mentioned method embodiments. The aforementioned storage media includes: removable storage devices, read-only memory (ROM), random access memory (RAM), magnetic disks or optical disks, and other media that can store program codes.

In some embodiments of the present disclosure, a medium is provided. There are computer-executable instructions in the medium, and the computer-executable instructions are executed by a processor to realize the operations in the compensation method described above.

Alternatively, the integrated unit described above in some embodiments of the disclosure can also be stored in a computer-readable storage medium if it is implemented in the form of a software function module and is sold or used as an independent product. Based on this understanding, the technical solutions of some embodiments of the present disclosure in essence or the part that makes contributions to some implementations can be embodied in the form of software products, which are stored in a storage medium and include several instructions to make a computer device (which can be a personal computer, a server, a network device, etc.) perform all or part of the methods described in various embodiments of the present disclosure. The aforementioned storage media include: removable storage devices, read-only memory (ROM), random access memory (RAM), magnetic disks or optical disks, and other media that can store program codes.

Some embodiments of the disclosure provide a compensation circuit module, a power amplification assembly, a compensation method and a device. The compensation circuit module at least includes a variable resistor, a detection component and a control component. The detection end of the detection component is connected with the DC blocking capacitor of the power amplifier and is configured to detect the voltage swing of the input signal of the DC blocking capacitor. The control component is connected with the detection component and is configured to output a control signal according to the input signal detected by the detection component. The variable resistor is connected with the output end of the control component and is configured to change the resistance connected to the power amplifier according to the control signal, and the resistance of the variable resistor connected to the power amplifier is configured to constitute the feedback resistance of the power amplifier. The feedback resistance is configured to increase when the gain of the power amplifier decreases. The increased feedback resistance is configured to keep the gain in the straight section of the gain change curve. The resistance of the variable resistor can be adjusted by the input signal to compensate the gain of the power amplifier and keep the linearity of the input and output of the power amplifier.

Various embodiments of the disclosure can have one or more of the following advantages.

A compensation circuit module provided by some embodiments of the disclosure at least includes a variable resistor, a detection component and a control component. A detection end of the detection component is connected with the DC blocking capacitor of the power amplifier and is configured to detect the voltage swing of the input signal of the DC blocking capacitor. The control component is connected with the detection component, and is configured to output a control signal according to the input signal detected by the detection component. Therefore, the detection component can be based on input signal parameters, it is determined that the control signal needs to be output according to the parameters of the input signal, and then the resistance of the variable resistor may be adjusted according to the input signal. The variable resistor is connected with the output end of the control component and is configured to change the resistance connected to the power amplifier according to the control signal, and the resistance of the variable resistor connected into the power amplifier is configured to constitute a feedback resistance of the power amplifier. The feedback resistance is configured to increase as the gain of the power amplifier decreases. The increased feedback resistance is configured to keep the gain in the straight section of the gain change curve. Therefore, compared with the fixed feedback resistance in the power amplifier, the resistance of the variable resistor constitutes the feedback resistance of the power amplifier, and the gain of the power amplifier can be compensated by adjusting the resistance of the variable resistor, so that the gain is stable, the linearity of the transistor voltage input signal output characteristics of the power amplifier in the case of large-amplitude signal input is maintained, and the nonlinear distortion of the power amplifier is prevented.

Various modifications of, and equivalent acts corresponding to, the disclosed aspects of the example embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

What is claimed is:

1. A compensation circuit module, comprising a variable resistor, a detection component and a control component; wherein
the detection component has a detection end, which is connected with a DC blocking capacitor of a power amplifier and is configured to detect a voltage swing of an input signal of the DC blocking capacitor;
the control component is connected with the detection component, and is configured to output a control signal according to the input signal detected by the detection component; and
the variable resistor is connected with an output end of the control component and is configured to change a resistance connected to the power amplifier according to the control signal, the resistance of the variable resistor connected to the power amplifier is configured to constitute a feedback resistance of the power amplifier, wherein the feedback resistance is configured to increase when gain of the power amplifier decreases, and the increased feedback resistance is configured to keep the gain in a straight section of a gain change curve.

2. The compensation circuit module according to claim 1, further comprising an isolation resistor, wherein the isolation resistor is connected with the output end of the control component, is connected with an input end of the variable resistor, and is configured to change the resistance of the variable resistor connected to the power amplifier according to the control signal and a resistance of the isolation resistor.

3. The compensation circuit module according to claim 1, wherein
the control component at least comprises a first sub-control component and a second sub-control component;
the first sub-control component is connected with the detection component and is configured to output a first control current proportional to the input signal according to the input signal of the DC blocking capacitor; and
the second sub-control component is connected with a back end of the first sub-control component and is configured to output a current control voltage inversely proportional to the first control current according to the first control current.

4. The compensation circuit module according to claim 3, wherein
a detector comprises the detection component and the first sub-control component;
the detection component of the detector is configured to detect the voltage swing of the input signal passing through the DC blocking capacitor; and
the detector is connected with a first control power supply to constitute the first sub-control component, and the first control power supply is configured to generate the first control voltage; the detector is further configured to determine the power threshold according to the first control voltage; according to the power threshold, the voltage swing that meets a preset condition is determined; according to the voltage swing that meets the preset condition, the first control current is output.

5. The compensation circuit module according to claim 3, wherein the second sub-control component at least comprises a voltage source, a voltage-controlled resistor, a second control power supply and a current mirror; wherein
the current mirror is connected with the voltage-controlled resistor, and is configured to receive the first control current and mirror the first control current to the voltage-controlled resistor;
the voltage-controlled resistor is connected with the second control power supply, and the second control power supply outputs a second control voltage, wherein the second control voltage is configured to control a resistance of the voltage-controlled resistor; and
an output end of a current control voltage is arranged between the voltage-controlled resistor and the current mirror, and is configured to output the current control voltage, wherein a voltage value of the current control voltage is equal to a voltage value of the voltage source minus a product of the voltage-controlled resistor and the first control current.

6. A power amplification assembly, comprising a power amplifier and a compensation circuit module according to claim 1, wherein
the power amplifier comprises a DC blocking capacitor arranged at a signal input end, a transistor, a bias circuit, a feedback circuit and a DC blocking capacitor arranged at a signal output end; and
a first end of the feedback circuit is connected with the DC blocking capacitor at the signal input end, the bias circuit and a gate of the transistor; a second end of the feedback circuit is connected with the DC blocking capacitor at the signal output end and a drain of the transistor; a feedback resistor of the feedback circuit at least comprises a fixed resistor and the variable resistor connected to the feedback circuit, the fixed resistor and the variable resistor are configured to constitute a feedback resistance of the power amplifier; the feedback resistance is configured to increase when the gain of the power amplifier decreases and the increased feedback resistance is configured to keep the gain in a straight section of the gain change curve.

7. A compensation method, utilizing the compensation circuit module according to claim 1 to compensate the gain of the power amplifier, the compensation method comprising:
detecting the input signal of the DC blocking capacitor by the detection component; and
outputting the control signal by the control component according to the input signal of the DC blocking capacitor, wherein, the control signal is configured to change the resistance connected to the power amplifier, the resistance of the variable resistor connected to the power amplifier and the fixed resistor constitute the feedback resistance, wherein the feedback resistance is configured to increase when the gain of the power amplifier decreases, the increased feedback resistance is configured to keep the gain in a straight section of the gain change curve.

8. The compensation method according to claim 7, further comprising:
outputting the first control current proportional to the input signal by the first sub-control component according to the input signal of the DC blocking capacitor; and
outputting the current control voltage inversely proportional to the first control current by the second sub-control component according to the first control current.

9. The compensation method according to claim 7, further comprising:
detecting and outputting the first control current by the detector, wherein the first control current is determined according to the voltage swing of the input signal of the DC blocking capacitor; determining the power threshold according to the first control voltage, and determining a power of the input signal according to the voltage swing of the input signal; outputting the first control current when a preset condition that the power of the input signal is greater than the power threshold is met, wherein the first control current is proportional to the power of the input signal.

10. The compensation method according to claim 7, further comprising:
receiving the first control current and mirroring the first control current to the voltage-controlled resistor by the current mirror;
outputting a second control voltage by a second control power supply, wherein the second control voltage is configured to control the resistance of the voltage-controlled resistor; and
outputting the current control voltage by the output end of the current control voltage arranged between the voltage-controlled resistor and the current mirror, wherein the voltage value of the current control voltage is equal to the voltage value of the voltage source minus the product of the voltage-controlled resistor and the first control current.

11. A device, comprising a memory and a processor configured to implement operations of the compensation method according to claim 7 by executing instructions stored in the memory.

12. The device of claim 11, wherein the resistance of the variable resistor constitutes the feedback resistance of the power amplifier, and the gain of the power amplifier is compensated by adjusting the resistance of the variable resistor, to thereby stabilize the gain and maintain linearity of transistor voltage input signal output characteristics of the power amplifier in a case of a large-amplitude signal input, while preventing nonlinear distortion of the power amplifier.
